(19) United States
(12) Patent Application Publication
(10) Pub. No.: US 2024/0388264 A1
(43) Pub. Date: Nov. 21, 2024

(54) DIFFERENTIAL POWER AMPLIFIER

(71) Applicant: Murata Manufacturing Co., Ltd., Kyoto (JP)

(72) Inventors: Masatoshi HASE, Kyoto (JP); Seiko NETSU, Kyoto (JP)

(21) Appl. No.: 18/785,713

(22) Filed: Jul. 26, 2024

Related U.S. Application Data
(63) Continuation of application No. PCT/JP2022/041205, filed on Nov. 4, 2022.

(30) Foreign Application Priority Data
Feb. 4, 2022 (JP) 2022-016370

(51) Int. Cl. H03F 3/217; H03F 3/195

(52) U.S. Cl. CPC H03F 3/2176; H03F 3/195; H03F 2200/451

(57) ABSTRACT

A Class E amplifier is configured to amplify a differential signal. Two output nodes of the Class E amplifier are connected to the power supply terminal with at least one choke inductor interposed therebetween. The Class E amplifier includes two transistors. The two transistors each includes a base or a gate connected to a corresponding one of two input nodes of the Class E amplifier and a collector or a drain connected to a corresponding one of the two output nodes of the Class E amplifier. First capacitors are each connected between the collector or the drain and an emitter or a source of a corresponding one of the two transistors. A first inductor is connected between the collector or the drain of one of the two transistors and the collector or the drain of the other of the two transistors.

### CROSS REFERENCE TO RELATED APPLICATION

This is a continuation of International Application No. PCT/JP2022/041205 filed on Nov. 4, 2022 which claims priority from Japanese Patent Application No. 2022-016370 filed on Feb. 4, 2022. The contents of these applications are incorporated herein by reference in their entireties.

### BACKGROUND ART

### Technical Field

The present disclosure relates to a differential power amplifier.

Highly efficient wide-band Class E amplifiers are known. Patent Document 1 below discloses a circuit configuration that enables a differential power amplifier to perform Class E operation. In the differential power amplifier configured to perform Class E operation, which is disclosed in Patent Document 1, a differential output is converted into a single-ended signal with a magnetically coupled transformer. The inductance of the primary coil of the magnetically coupled transformer is used as the inductance for Class E operation.
Patent Document 1: U.S. Pat. No. 10,110,184

### BRIEF SUMMARY

The differential power amplifier disclosed in Patent Document 1 is subject to an effect of an inter-wire parasitic capacitance of the primary coil of the magnetically coupled transformer, and thus the operation frequency of Class E operation is difficult to increase. The disclosure provides a differential power amplifier that may enable Class E operation in a radio frequency.

According to an aspect of the present disclosure,
there is provided a differential power amplifier including:
a Class E amplifier having two input nodes and two output nodes and configured to amplify a differential signal;
a power supply terminal configured to receive a power supply voltage; and
at least one choke inductor connecting the two output nodes to the power supply terminal,
and the Class E amplifier includes
two transistors each including a base or a gate connected to a corresponding one of the two input nodes and a collector or a drain connected to a corresponding one of the two output nodes,
two first capacitors each connected between the collector or the drain and an emitter or a source of a corresponding one of the two transistors, and
a first inductor connected between the collector or the drain of one of the two transistors and the collector or the drain of the other of the two transistors.

The first inductor is connected separately from the at least one choke inductor, and the two first capacitors and the first inductor are adjusted to satisfy a condition for Class E operation. Since the condition for Class E operation is independent of the at least one choke inductor, the operation frequency of the Class E amplifier may be increased.

### BRIEF DESCRIPTION OF THE DRAWINGS

FIG. 1 is an equivalent circuit diagram of a differential power amplifier according to a first embodiment.

FIG. 2 is an equivalent circuit diagram of a differential power amplifier according to a second embodiment.

FIG. 3 is an equivalent circuit diagram illustrating a specific example of the differential power amplifier according to the second embodiment.

FIG. 4 is an equivalent circuit diagram illustrating another specific example of the differential power amplifier according to the second embodiment.

FIG. 5 is an equivalent circuit diagram illustrating a still another specific example of the differential power amplifier according to the second embodiment.

FIG. 6 is an equivalent circuit diagram illustrating a still another specific example of the differential power amplifier according to the second embodiment.

FIG. 7 is an equivalent circuit diagram illustrating a still another specific example of the differential power amplifier according to the second embodiment.

FIG. 8 is an equivalent circuit diagram illustrating a still another specific example of the differential power amplifier according to the second embodiment.

FIG. 9 is an equivalent circuit diagram illustrating a still another specific example of the differential power amplifier according to the second embodiment.

FIG. 10 is an equivalent circuit diagram illustrating a still another specific example of the differential power amplifier according to the second embodiment.

FIG. 11 is an equivalent circuit diagram illustrating a still another specific example of the differential power amplifier according to the second embodiment.

FIG. 12 is an equivalent circuit diagram of a differential power amplifier according to a third embodiment.

FIG. 13 is an equivalent circuit diagram illustrating a specific example of the differential power amplifier according to the third embodiment.

FIG. 14 is an equivalent circuit diagram illustrating another specific example of the differential power amplifier according to the third embodiment.

FIG. 15 is an equivalent circuit diagram illustrating a still another specific example of the differential power amplifier according to the third embodiment.

FIG. 16 is an equivalent circuit diagram of a differential power amplifier according to a fourth embodiment.

### DETAILED DESCRIPTION

### First Embodiment

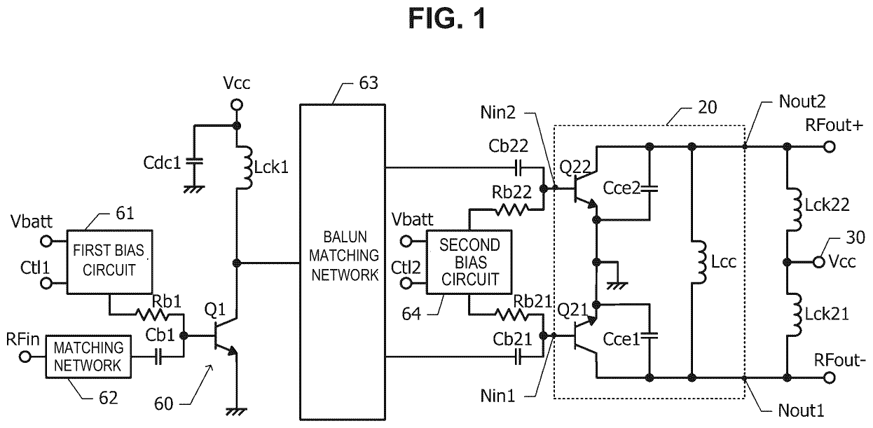

Referring to FIG. 1, description will be given with regard to a differential power amplifier according to a first embodiment. FIG. 1 is an equivalent circuit diagram of the differential power amplifier according to the first embodiment. The differential power amplifier according to the first embodiment includes a transistor Q1 to form a driver-stage amplifier 60, a balun matching network 63, and a Class E amplifier 20 in a power stage. The driver-stage amplifier 60 is configured to output a single-ended signal.

The single-ended signal that is output from the driver-stage amplifier 60 is converted into a differential signal by the balun matching network 63 and is input to the Class E amplifier 20. The Class E amplifier 20 is configured to amplify the differential signal.

Next, a configuration of the driver-stage amplifier 60 will be described. A radio-frequency input signal RFin is input to the base of the transistor Q1 via a matching network 62 and an input capacitor Cb1. A bias voltage Vbatt is supplied to a first bias circuit 61. The first bias circuit 61 is configured to supply a base bias voltage to the transistor Q1 via a ballast resistor Rbl based on a control signal Ctl1. A power supply voltage Vcc is applied to the collector of the transistor Q1 via a choke coil Lck1. The terminal for receiving the power supply voltage Vcc is connected to ground potential with a bypass capacitor Cdc1 interposed therebetween.

The single-ended signal that is output from the driver-stage amplifier 60 is input to the balun matching network 63. The balun matching network 63 is configured to convert a single-ended signal into a differential signal and perform impedance conversion.

Next, a configuration of the Class E amplifier 20 will be described. The Class E amplifier 20 includes transistors Q21 and Q22, first capacitors Cce1 and Cce2, and a first inductor Lcc. For example, hetero-junction bipolar transistors are used as the transistors Q21 and Q22. The bases of the transistors Q21 and Q22 are connected to two input nodes Nin1 and Nin2, respectively, and the collectors of the transistors Q21 and Q22 are connected to two output nodes Nout1 and Nout2, respectively.

The first capacitors Cce1 and Cce2 are connected between the collectors and the emitters of the transistors Q21 and Q22, respectively. The emitters of the transistors Q21 and Q22 are grounded. The first inductor Lcc is connected between the collector of the transistor Q21 on one side and the collector of the transistor Q22 on the other side. Circuit parameters of the first capacitors Cce1 and Cce2 and the first inductor Lcc are set so that the Class E amplifier 20 may perform Class E operation in the operation frequency range.

The differential signal that is output from the balun matching network 63 is input to the two input nodes Nin1 and Nin2 of the Class E amplifier 20 via the input capacitors Cb21 and Cb22, respectively. The bias voltage Vbatt is supplied to a second bias circuit 64. The second bias circuit 64 is configured to supply base bias voltages to the bases of the transistors Q21 and Q22 via ballast resistors Rb21 and Rb22, respectively, based on a control signal Ct12. A differential signal RFout+ and RFout−, which is amplified by the Class E amplifier 20, is output from the two output nodes Nout2 and Nout1, respectively.

Next, a configuration of the power supply circuit of the Class E amplifier 20 will be described. The two output nodes Nout1 and Nout2 of the Class E amplifier 20 are connected to a power supply terminal 30 with choke coils Lck21 and Lck22, respectively, interposed therebetween. The power supply voltage Vcc is applied to the collectors of the transistors Q21 and Q22 from the power supply terminal 30 via the choke coils Lck21 and Lck22, respectively.

Next, description will be given with regard to a positive effect according to the first embodiment.

To cause the Class E amplifier 20 to perform Class E operation, the first inductor Lcc is disposed separately from the choke coils Lck21 and Lck22 for power supply. This configuration allows the use of inductors, as the choke coils Lck21 and Lck22, each having an inductance value adequate to cut off radio frequency also in a frequency range outside the operation frequency range. Consequently, leakage of a noise signal from the power supply terminal 30 and parasitic oscillation may be reduced or prevented.

In particular, the optimal value of the first inductor Lcc decreases as the operation frequency increases. Since the first inductor Lcc is disposed separately from the choke coils Lck21 and Lck22 in the power supply circuit, the inductance of the first inductor Lcc may be set to a small value independently of the inductances of the choke coils Lck21 and Lck22. Accordingly, a frequency range including higher operation frequencies may be handled. In particular, the first inductor Lcc and the first capacitors Cce1 and Cce2 can be integrated with the transistors Q21 and Q22 on the same substrate to reduce parasitic inductance of wiring connected to the first inductor Lcc.

Next, description will be given with regard to a differential power amplifier according to a modification of the first embodiment.

Although hetero-junction bipolar transistors are used as the transistors Q21 and Q22 in the first embodiment, field-effect transistors, such as a MISFET (Metal-Insulator-Semiconductor Field Effect Transistor), a MESFET (Metal-Semiconductor Field Effect Transistor), and a HEMT (High Electron Mobility Transistor) may be used. In such a case, the drains of two transistors are connected one each to the two output nodes Nout1 and Nout2, and the gates are connected one each to the two input nodes Nin1 and Nin2. The sources of the two transistors are grounded.

### Second Embodiment

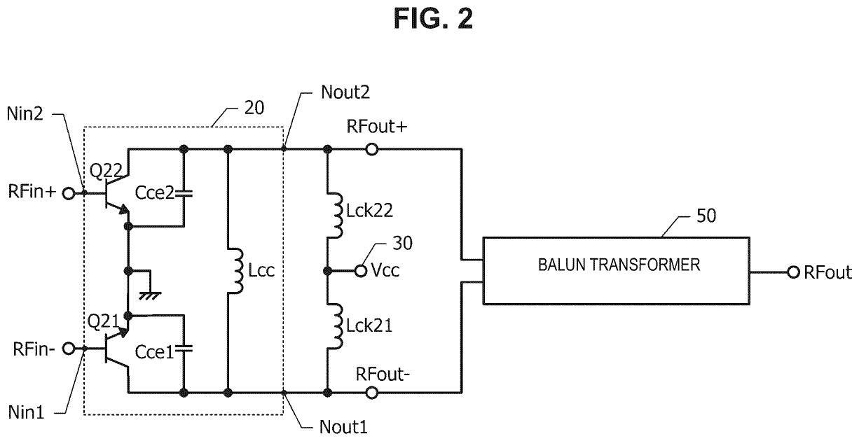

Next, referring to FIG. 2, description will be given with regard to a differential power amplifier according to a second embodiment. Description will be omitted herein with regard to the configuration that is the same as the configuration of the differential power amplifier according to the first embodiment (FIG. 1).

FIG. 2 is an equivalent circuit diagram of the differential power amplifier according to the second embodiment. In FIG. 2, circuits located upstream of two input nodes Nin1 and Nin2 of a Class E amplifier 20 are not illustrated. A balun transformer 50 is connected to two output nodes Nout1 and Nout2 of the Class E amplifier 20. The balun transformer 50 is configured to provide functions, such as a balun (balanced-unbalanced converting circuit), an impedance converting circuit, and a band elimination filter. A single-ended signal RFout is output from the balun transformer 50.

Next, description will be given with regard to a positive effect according to the second embodiment.

Since a first inductor Lcc is disposed separately from choke coils Lck21 and Lck22 for power supply also in the second embodiment as in the first embodiment, leakage of a noise signal from the power supply terminal 30 and parasitic oscillation may be reduced or prevented. In addition, the operation frequency may be increased.

A balun has a function of attenuating even harmonics. A combination of a balun and a band elimination filter having characteristics of stopping odd harmonics enables the balun transformer 50 to have bandpass characteristics of passing only the fundamental. Consequently, a band pass filter configured to pass only the fundamental need not be separately disposed, contributing to cost reduction and downsizing.

In a transmission line transformer, an inter-line parasitic capacitance does not lead to degraded characteristics because the inter-line capacitance is also one of the constituent elements to achieve the functionality. The transmission line transformer configured to provide the functions of a balun, an impedance converting circuit, and a band elimination filter may lead to broad band operation also in a radio-frequency range in which the effect of parasitic capacitance is large.

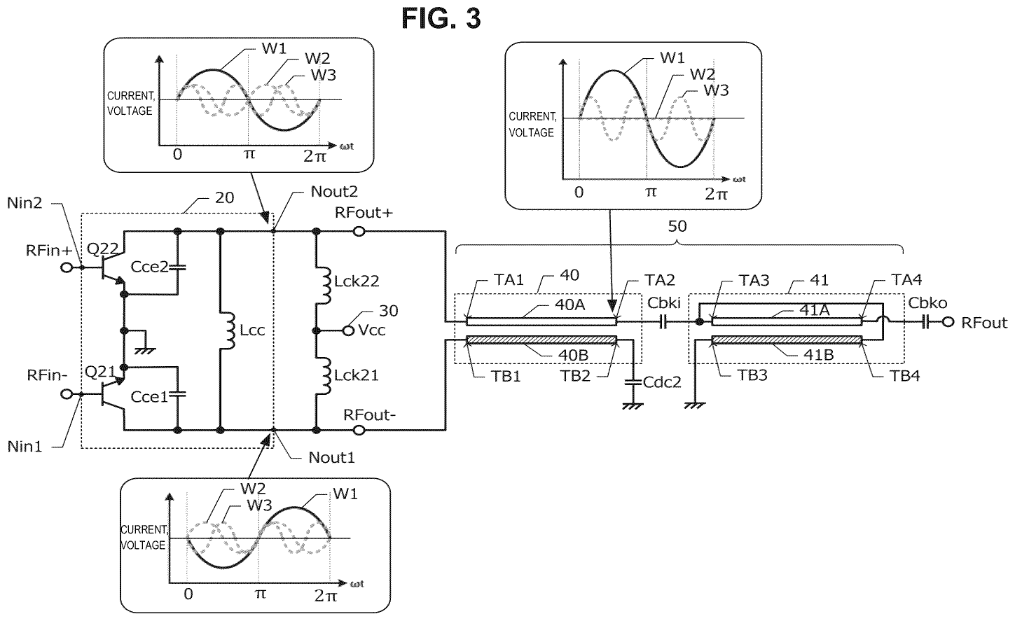

Next, referring to FIGS. 3 to 11, description will be given with regard to various specific examples of the differential power amplifier according to the second embodiment.

FIG. 3 is an equivalent circuit diagram illustrating a specific example of the differential power amplifier according to the second embodiment. In the specific example illustrated in FIG. 3, the balun transformer 50 includes a common mode choke 40 and a Ruthroff type transmission line transformer 41, which are arranged in a cascading connection. One end portion of the transmission line included in the common mode choke 40 is defined as a first end, and the other end portion is defined as a second end. One end portion of the transmission line included in the Ruthroff type transmission line transformer 41 is defined as a third end, and the other end portion is defined as a fourth end. The first end, the second end, the third end, and the fourth end are also defined for primary lines and secondary lines included in the transmission lines.

FIG. 3 illustrates examples of current or voltage waveforms of the fundamental W1, the second harmonic W2, and the third harmonic W3 at the two output nodes Nout1 and Nout2 and at the second end TA2 of a primary line 40A of the common mode choke 40. The horizontal axis of each waveform represents ωt, where ω denotes the angular frequency and t denotes time.

The common mode choke 40 includes the primary line 40A and a secondary line 40B coupled to each other, and the Ruthroff type transmission line transformer 41 includes a primary line 41A and a secondary line 41B coupled to each other. In FIG. 3, the primary lines 40A and 41A are represented by unfilled rectangles, and the secondary lines 40B and 41B are represented by hatched rectangles. In the following drawings, the primary line of a transmission line transformer is also represented by an unfilled rectangle, and the secondary line is also represented by a hatched rectangle.

The first end TA1 of the primary line 40A and the first end TB1 of the secondary line 40B of the common mode choke 40 are connected to the two output nodes Nout2 and Nout1, respectively, of the Class E amplifier 20. The second end TB2 of the secondary line 40B is connected to ground potential with a DC-cut capacitor Cdc2 interposed therebetween. In other words, the second end TB2 of the secondary line 40B is connected to ground potential for alternating current. The common mode choke 40 is configured to convert a differential signal received from the Class E amplifier 20 into a single-ended signal and output the single-ended signal from the second end TA2 of the primary line 40A.

The third end TA3 of the primary line 41A of the Ruthroff type transmission line transformer 41 is connected to the second end TA2 of the primary line 40A of the common mode choke 40 with a DC-cut capacitor Cbki interposed therebetween. The third end TB3 of the secondary line 41B is directly connected to ground potential. In other words, the third end TB3 of the secondary line 41B is connected to ground potential for alternating current and direct current. The fourth end TB4 of the secondary line 41B is connected to the third end TA3 of the primary line 41A. A single-ended signal RFout is output from the fourth end TA4 of the primary line 41A via a DC-cut capacitor Cbko.

The power supply voltage Vcc, which is applied to the secondary line 40B of the common mode choke 40 from the power supply terminal 30 via the choke coil Lck21, is separated from ground potential for direct current by the DC-cut capacitor Cdc2. The power supply voltage Vcc, which is applied to the primary line 40A of the common mode choke 40 from the power supply terminal 30 via the choke coil Lck22, is separated from ground potential for direct current by the DC-cut capacitor Cbki.

In the specific example illustrated in FIG. 3, the common mode choke 40 is configured to serve as a balun (balanced-unbalanced converting circuit). The common mode choke 40 is capable of operating as a balun not only in a frequency range of the fundamental but also in a frequency range including frequencies equal to or higher than the second harmonic frequency. Specifically, the common mode choke 40 is configured to receive signals that are output from the output nodes Nout1 and Nout2 not only in the frequency range of the fundamental W1 but also in the frequency ranges of odd and even harmonics, combine the signals from the output nodes Nout1 and Nout2 after increasing or decreasing the phase difference between these signals by 180° to obtain a composite signal, and output the composite signal from the second end TA2 of the primary line 40A.

An output signal y(t) is given by the following equation when a signal x(t) is input to an amplification circuit having nonlinear characteristics:

$$y ( t ) = {c}_{0} + {c}_{1} x ( t ) + {{c}_{2} [ x ( t ) ]}^{2} + {{c}_{3} [ x ( t ) ]}^{3} + … . \qquad ( 1 )$$

Here, c₀, c₁, c₂, c₃, . . . are constants determined by the characteristics of the amplification circuit, and t represents time.

As can be seen in Equation (1) above, even harmonics generated in a nonlinear device such as a transistor are not affected by the sign of the input signal in the frequency range of the fundamental. Accordingly, even harmonics (such as the second harmonic W2) that are output from the output nodes Nout1 and Nout2 are in phase. Since being capable of operating as a balun also in the frequency range including frequencies equal to or higher than the second harmonic frequency, the common mode choke 40 is configured to attenuate even harmonics. Consequently, signal levels of even harmonics (such as the second harmonic W2) that are output from the second end TA2 of the primary line 40A of the common mode choke 40 are approximately zero.

The Ruthroff type transmission line transformer 41 is configured to serve as an impedance converting circuit and a band elimination filter. For example, the Ruthroff type transmission line transformer 41 is theoretically able to cause the input impedance to be shorted at the fourth harmonic frequency, and the attenuation (amount of signal elimination) becomes largest at this frequency. Since the attenuation gradually increases in practice with the frequency in the frequency range of the third harmonic, the third harmonic may be attenuated by using the Ruthroff type transmission line transformer 41.

Since the common mode choke 40 is configured to attenuate even harmonics and the Ruthroff type transmission line transformer 41 is configured to attenuate the third harmonic, the balun transformer 50 serves as a band pass filter configured to pass the fundamental.

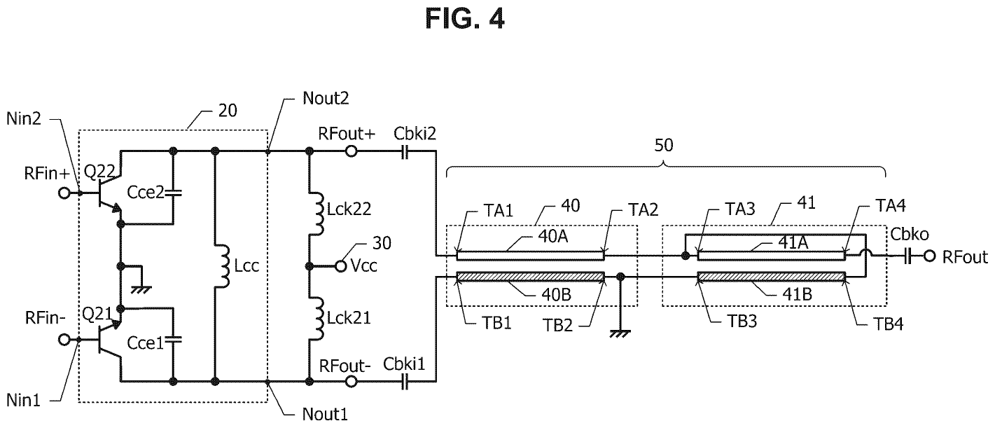

FIG. 4 is an equivalent circuit diagram illustrating another specific example of the differential power amplifier according to the second embodiment. The differential power amplifier in the specific example illustrated in FIG. 4 includes neither of the DC-cut capacitors Cbki and Cdc2 included in the specific example illustrated in FIG. 3. The second end TA2 of the primary line 40A of the common mode choke 40 is directly connected to the third end TA3 of the primary line 41A of the Ruthroff type transmission line transformer 41, and the second end TB2 of the secondary line 40B of the common mode choke 40 is directly connected to ground potential.

In the specific example illustrated in FIG. 4, the two output nodes Nout1 and Nout2 of the Class E amplifier 20 are connected to the balun transformer 50 with DC-cut capacitors Cbki1 and Cbki2, respectively, interposed therebetween. For direct current, the DC-cut capacitors Cbki1 and Cbki2 separate the power supply voltage Vcc from ground potential, to which the balun transformer 50 is connected.

In the specific example illustrated in FIG. 4, no DC-cut capacitor is inserted between the common mode choke 40 and the Ruthroff type transmission line transformer 41. Thus, the primary line 40A of the common mode choke 40 and the primary line 41A of the Ruthroff type transmission line transformer 41 may be formed as a single continuous conductor trace, and the secondary line 40B of the common mode choke 40 and the secondary line 41B of the Ruthroff type transmission line transformer 41 may be formed as a single continuous conductor trace. Such a structure may contribute to cost reduction and downsizing of the differential power amplifier.

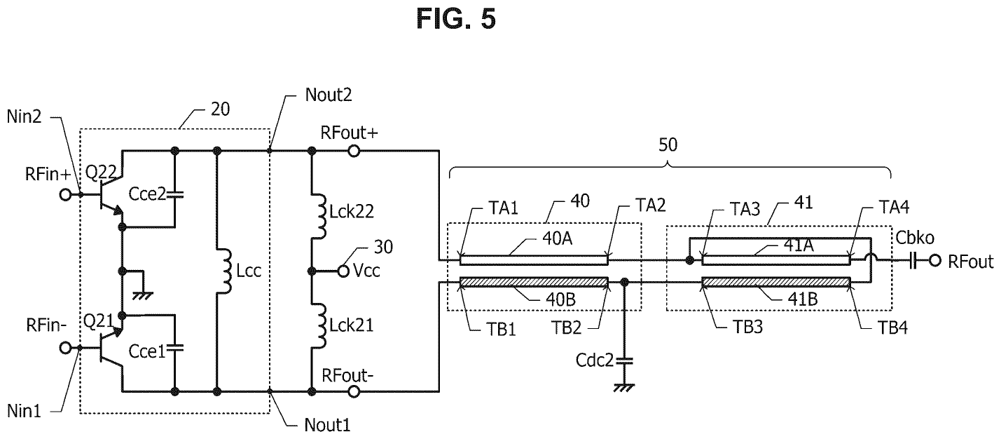

FIG. 5 is an equivalent circuit diagram illustrating a still another specific example of the differential power amplifier according to the second embodiment. The differential power amplifier in the specific example illustrated in FIG. 5 does not include the DC-cut capacitor Cbki included in the specific example illustrated in FIG. 3. The second end TA2 of the primary line 40A of the common mode choke 40 is directly connected to the third end TA3 of the primary line 41A of the Ruthroff type transmission line transformer 41. The third end TB3 of the secondary line 41B of the Ruthroff type transmission line transformer 41 is not directly connected to ground potential but is connected to ground potential with the DC-cut capacitor Cdc2 interposed therebetween. In this configuration, for direct current, the power supply voltage Vcc is separated from ground potential, to which the secondary lines 40B and 41B of the balun transformer 50 are connected.

Also in the specific example illustrated in FIG. 5 as in the specific example illustrated in FIG. 4, the primary line 40A of the common mode choke 40 and the primary line 41A of the Ruthroff type transmission line transformer 41 may be formed as a single continuous conductor trace, and the secondary line 40B of the common mode choke 40 and the secondary line 41B of the Ruthroff type transmission line transformer 41 may be formed as a single continuous conductor trace. Such a structure may contribute to cost reduction and downsizing of the differential power amplifier.

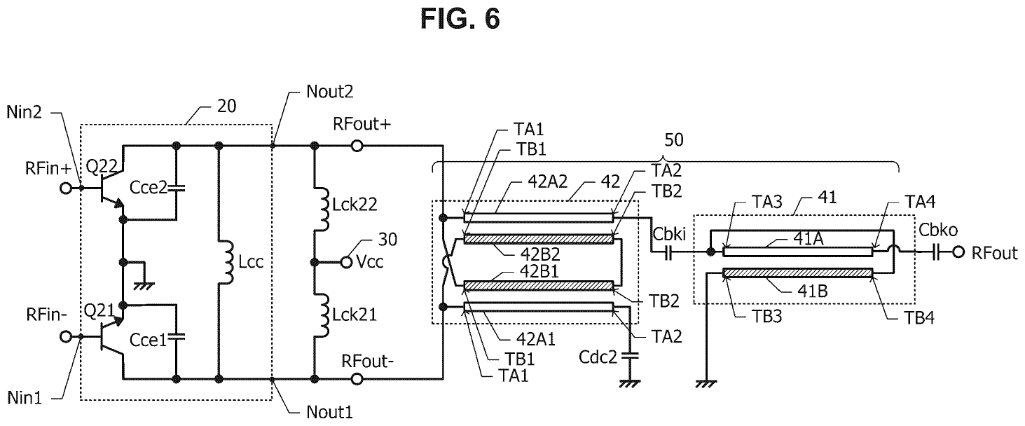

FIG. 6 is an equivalent circuit diagram illustrating a still another specific example of the differential power amplifier according to the second embodiment. In the specific example illustrated in FIG. 6, the balun transformer 50 includes a Guanella type transmission line transformer 42 and a Ruthroff type transmission line transformer 41, which are arranged in a cascading connection. One end portion of the transmission line included in the Guanella type transmission line transformer 42 is defined as a first end, and the other end portion is defined as a second end. One end portion of the transmission line included in the Ruthroff type transmission line transformer 41 is defined as a third end, and the other end portion is defined as a fourth end.

The Guanella type transmission line transformer 42 includes coupled transmission lines consisting of a primary line 42A1 and a secondary line 42B1 coupled to each other and coupled transmission lines consisting of a primary line 42A2 and a secondary line 42B2 coupled to each other. The first end TB1 of the secondary line 42B1 is connected to the first end TAI of the primary line 42A2, and the first end TB1 of the secondary line 42B2 is connected to the first end TA1 of the primary line 42A1. The second ends TB2 of the two secondary lines 42B1 and 42B2 are connected to each other. The configuration of the Ruthroff type transmission line transformer 41 is the same as the configuration of the Ruthroff type transmission line transformer 41 in the specific example illustrated in FIG. 3.

The first end TA1 of the primary line 42A1 on one side and the first end TA1 of the primary line 42A2 on the other side are connected to the two output nodes Nout1 and Nout2, respectively, of the Class E amplifier 20. The second end TA2 of the primary line 42A1 is connected to ground potential with the DC-cut capacitor Cdc2 interposed therebetween. In other words, the second end TA2 of the primary line 42A1 is connected to ground potential for alternating current. The second end TA2 of the primary line 42A2 is connected to the third end TA3 of the primary line 41A of the Ruthroff type transmission line transformer 41 with the DC-cut capacitor Cbki interposed therebetween.

The Guanella type transmission line transformer 42 is configured to provide a function of a balun and a function of an impedance converting circuit. The Ruthroff type transmission line transformer 41 is configured to provide a function of an impedance converting circuit and a function of a band elimination filter. For direct current, the DC-cut capacitors Cdc2 and Cbki separate the power supply voltage Vcc from ground potential, to which the primary line 42A1 of the Guanella type transmission line transformer 42 is connected, and ground potential, to which the secondary line 41B of the Ruthroff type transmission line transformer 41 is connected.

Even harmonics may be attenuated by a common mode elimination function of the Guanella type transmission line transformer 42. The Ruthroff type transmission line transformer 41 is capable of attenuating the third harmonic as in the specific example illustrated in FIG. 3. Since the Guanella type transmission line transformer 42 and the Ruthroff type transmission line transformer 41 both have the impedance conversion function, the overall impedance conversion ratio may be increased.

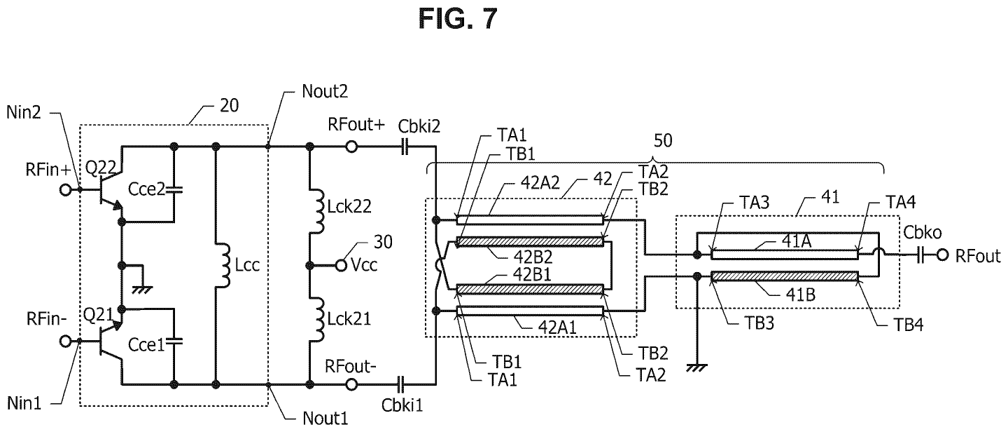

FIG. 7 is an equivalent circuit diagram illustrating a still another specific example of the differential power amplifier according to the second embodiment. The differential power amplifier in the specific example illustrated in FIG. 7 includes neither of the DC-cut capacitors Cdc2 and Cbki included in the specific example illustrated in FIG. 6. The second end TA2 of the primary line 42A2 of the Guanella type transmission line transformer 42 is directly connected to the third end TA3 of the primary line 41A of the Ruthroff type transmission line transformer 41, and the second end TA2 of the primary line 42A1 of the Guanella type transmission line transformer 42 is directly connected to ground potential. Further, in the specific example illustrated in FIG. 7, the output nodes Nout1 and Nout2 of the Class E amplifier 20 are connected to the balun transformer 50 with the DC-cut capacitors Cbki1 and Cbki2, respectively, interposed therebetween.

For direct current, the DC-cut capacitors Cbki1 and Cbki2 separate the power supply voltage Vcc from ground potential, to which the primary line 42A1 of the Guanella type transmission line transformer 42 and the secondary line 41B of the Ruthroff type transmission line transformer 41 are connected.

In the specific example illustrated in FIG. 7, the primary line 42A1 of the Guanella type transmission line transformer 42 and the secondary line 41B of the Ruthroff type transmission line transformer 41 may be formed as a single continuous conductor trace, and the primary line 42A2 of the Guanella type transmission line transformer 42 and the primary line 41A of the Ruthroff type transmission line transformer 41 may be formed as a single continuous conductor trace.

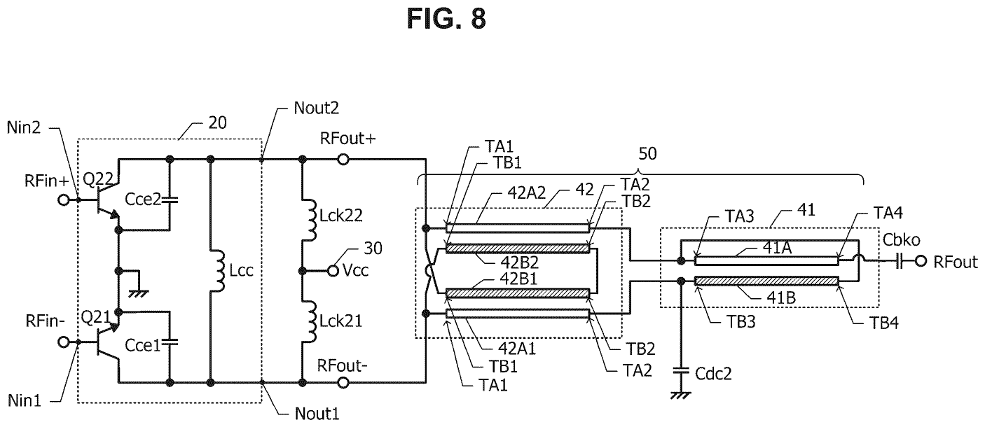

FIG. 8 is an equivalent circuit diagram illustrating a still another specific example of the differential power amplifier according to the second embodiment. The differential power amplifier in the specific example illustrated in FIG. 8 does not include the DC-cut capacitor Cbki included in the specific example illustrated in FIG. 6. The second end TA2 of the primary line 42A2 of the Guanella type transmission line transformer 42 is directly connected to the third end TA3 of the primary line 41A of the Ruthroff type transmission line transformer 41. The DC-cut capacitor Cbki is removed, and instead the third end TB3 of the secondary line 41B of the Ruthroff type transmission line transformer 41 is connected to ground potential with the DC-cut capacitor Cdc2 interposed therebetween. Specifically, the second end TA2 of the primary line 42A1 of the Guanella type transmission line transformer 42 and the third end TB3 of the secondary line 41B of the Ruthroff type transmission line transformer 41 are connected to each other and are connected to ground potential for alternating current. For direct current, the DC-cut capacitor Cdc2 separates the power supply voltage Vcc from ground potential, to which the primary line 42A1 of the Guanella type transmission line transformer 42 and the secondary line 41B of the Ruthroff type transmission line transformer 41 are connected.

Also in the specific example illustrated in FIG. 8 as in the specific example illustrated in FIG. 7, the primary line 42A1 of the Guanella type transmission line transformer 42 and the secondary line 41B of the Ruthroff type transmission line transformer 41 may be formed as a single continuous conductor trace, and the primary line 42A2 of the Guanella type transmission line transformer 42 and the primary line 41A of the Ruthroff type transmission line transformer 41 may be formed as a single continuous conductor trace.

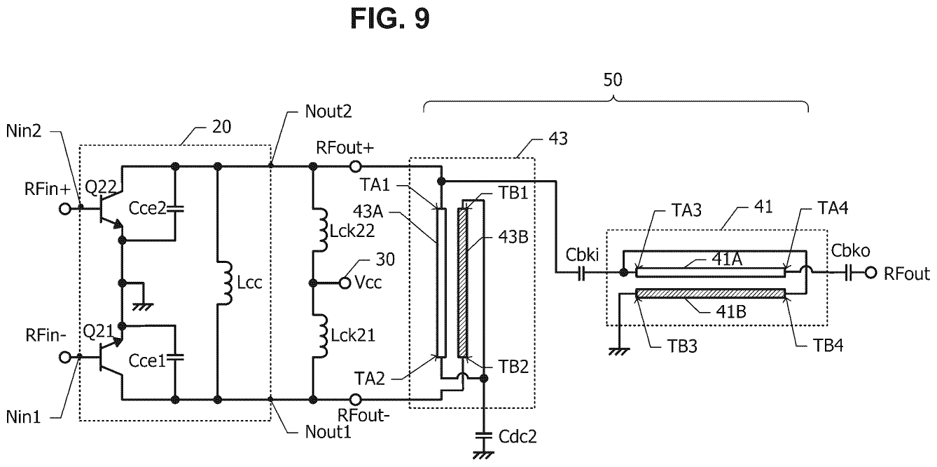

FIG. 9 is an equivalent circuit diagram illustrating a still another specific example of the differential power amplifier according to the second embodiment. In the specific example illustrated in FIG. 9, the balun transformer 50 includes a first Ruthroff type transmission line transformer 43 and a second Ruthroff type transmission line transformer 41, which are arranged in a cascading connection. One end portion of the transmission line included in the first Ruthroff type transmission line transformer 43 is defined as a first end, and the other end portion is defined as a second end. One end portion of the transmission line included in the second Ruthroff type transmission line transformer 41 is defined as a third end, and the other end portion is defined as a fourth end.

The first Ruthroff type transmission line transformer 43 includes a primary line 43A and a secondary line 43B coupled to each other. The first end TA1 of the primary line 43A is connected to the output node Nout2 on one side of the Class E amplifier 20. The second end TA2 of the primary line 43A is connected to the first end TB1 of the secondary line 43B. The second end TB2 of the secondary line 43B is connected to the output node Nout1 on the other side of the Class E amplifier 20. The second end TA2 of the primary line 43A and the first end TB1 of the secondary line 43B are connected to ground potential with the DC-cut capacitor Cdc2 interposed therebetween.

The configuration of the second Ruthroff type transmission line transformer 41 is the same as the configuration of the Ruthroff type transmission line transformer 41 in the specific example illustrated in FIG. 3. The third end TA3 of the primary line 41A of the second Ruthroff type transmission line transformer 41 is connected to the first end TA1 of the primary line 43A of the first Ruthroff type transmission line transformer 43 with the DC-cut capacitor Cbki interposed therebetween.

For direct current, the DC-cut capacitor Cdc2 separates the power supply voltage Vcc from ground potential, to which the first Ruthroff type transmission line transformer 43 is connected. For direct current, the DC-cut capacitor Cbki separates the power supply voltage Vcc from ground potential, to which the secondary line 41B of the second Ruthroff type transmission line transformer 41 is connected.

The first Ruthroff type transmission line transformer 43 is configured to serve as a balun, and the second Ruthroff type transmission line transformer 41 is configured to serve as an impedance converting circuit and a band elimination filter. The optimal value of the line length for the first Ruthroff type transmission line transformer 43 configured to serve as a balun is 1/8 of the wavelength at the operation frequency and is shorter than the optimal values of the line length for the common mode choke 40 (FIGS. 3, 4, and 5) and the Guanella type transmission line transformer 42 (FIGS. 6, 7, and 8). Such a structure may contribute to cost reduction and downsizing.

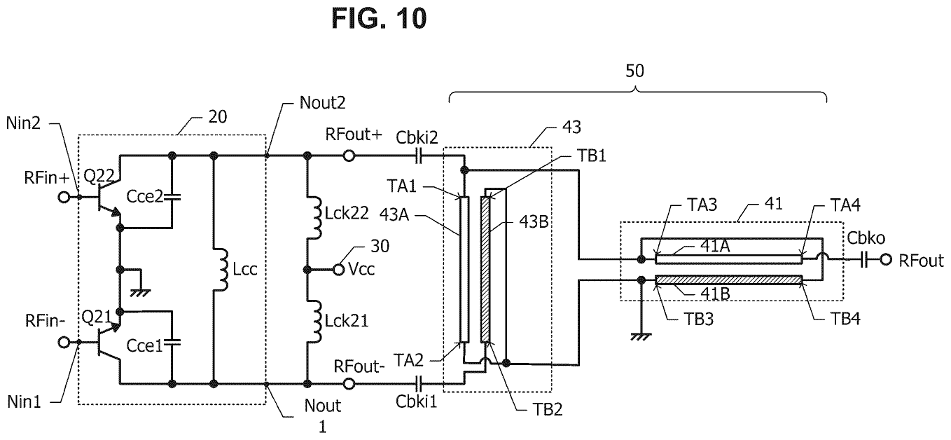

FIG. 10 is an equivalent circuit diagram illustrating a still another specific example of the differential power amplifier according to the second embodiment. The differential power amplifier in the specific example illustrated in FIG. 10 includes neither of the DC-cut capacitors Cdc2 and Cbki included in the specific example illustrated in FIG. 9. The first end TA1 of the primary line 43A of the first Ruthroff type transmission line transformer 43 is directly connected to the third end TA3 of the primary line 41A of the second Ruthroff type transmission line transformer 41, and the second end TA2 of the primary line 43A and the first end TB1 of the secondary line 43B of the first Ruthroff type transmission line transformer 43 is directly connected to ground potential. Further, in the specific example illustrated in FIG. 10, the two output nodes Nout1 and Nout2 of the Class E amplifier 20 are connected to the balun transformer 50 with the DC-cut capacitors Cbki1 and Cbki2, respectively, interposed therebetween.

In the specific example illustrated in FIG. 10, the primary line 43A of the first Ruthroff type transmission line transformer 43 and the primary line 41A of the second Ruthroff type transmission line transformer 41 may be formed as a single continuous conductor trace, and the secondary line 43B of the first Ruthroff type transmission line transformer 43 and the secondary line 41B of the second Ruthroff type transmission line transformer 41 may be formed as a single continuous conductor trace. Such a structure may contribute to cost reduction and downsizing of the differential power amplifier.

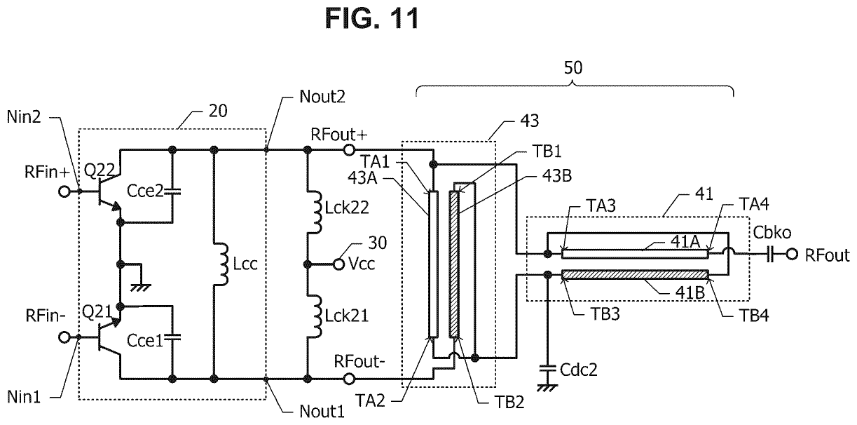

The differential power amplifier in the specific example illustrated in FIG. 11 does not include the DC-cut capacitor Cbki included in the specific example illustrated in FIG. 9. The first end TA1 of the primary line 43A of the first Ruthroff type transmission line transformer 43 is directly connected to the third end TA3 of the primary line 41A of the second Ruthroff type transmission line transformer 41. The DC-cut capacitor Cbki is removed, and instead the third end TB3 of the secondary line 41B of the second Ruthroff type transmission line transformer 41 is connected to ground potential with the DC-cut capacitor Cdc2 interposed therebetween. For direct current, the DC-cut capacitor Cdc2 separates the power supply voltage Vcc from ground potential.

Also in the specific example illustrated in FIG. 11 as in the specific example illustrated in FIG. 10, the primary line 43A of the first Ruthroff type transmission line transformer 43 and the primary line 41A of the second Ruthroff type transmission line transformer 41 may be formed as a single continuous conductor trace, and the secondary line 43B of the first Ruthroff type transmission line transformer 43 and the secondary line 41B of the second Ruthroff type transmission line transformer 41 may be formed as a single continuous conductor trace. Such a structure may contribute to cost reduction and downsizing of the differential power amplifier.

### Third Embodiment

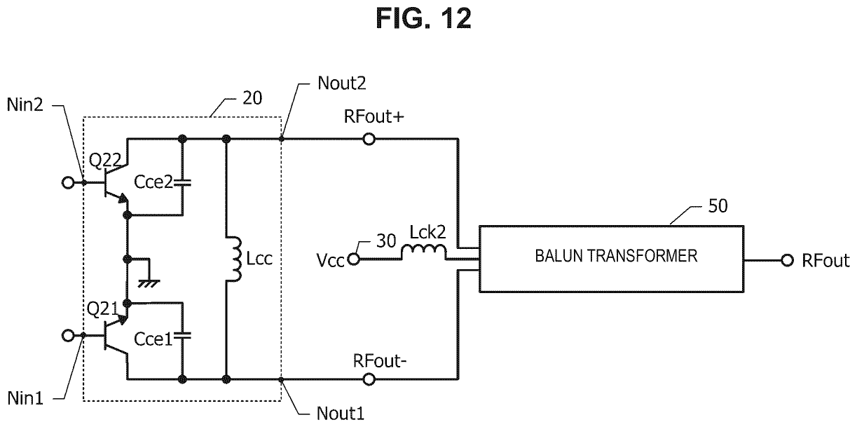

Next, referring to FIG. 12, description will be given with regard to a differential power amplifier according to a third embodiment. Description will be omitted herein with regard to the configuration that is the same as the configuration of the differential power amplifier according to the second embodiment (FIG. 2).

FIG. 12 is an equivalent circuit diagram of the differential power amplifier according to the third embodiment. In the second embodiment (FIG. 2), the power supply terminal 30 is connected to the two output nodes Nout1 and Nout2 of the Class E amplifier 20 with the choke coils Lck21 and Lck22, respectively, interposed therebetween. Namely, the power supply voltage Vcc is applied to the Class E amplifier 20 without necessarily passing through the balun transformer 50. In contrast to such a configuration, in the third embodiment, the power supply voltage Vcc is applied to the two output nodes Nout1 and Nout2 of the Class E amplifier 20 via a choke coil Lck2 and a balun transformer 50.

The balun transformer 50 is configured to provide functions, such as a balun, an impedance converting circuit, and a band elimination filter as in the second embodiment (FIG. 2).

Next, description will be given with regard to a positive effect according to the third embodiment.

Since the first inductor Lcc is disposed separately from the choke coil Lck2 for power supply also in the third embodiment as in the first embodiment, leakage of a noise signal from the power supply terminal 30 and parasitic oscillation may be reduced or prevented.

Further, the balun transformer 50 may have bandpass characteristics of passing only the fundamental also in the third embodiment as in the second embodiment (FIG. 2). Consequently, a band pass filter configured to pass only the fundamental need not be separately disposed, contributing to cost reduction and downsizing. In addition, as in the second embodiment (FIG. 2), broad band operation may be achieved also in a radio-frequency range in which the effect of parasitic capacitance is large.

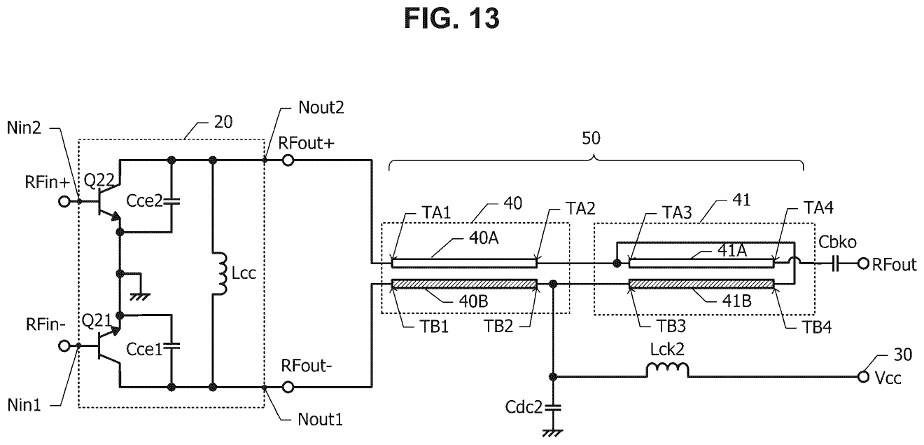

Next, referring to FIGS. 13 to 15, description will be given with regard to specific examples of the differential power amplifier according to the third embodiment.

FIG. 13 is an equivalent circuit diagram illustrating a specific example of the differential power amplifier according to the third embodiment. In the specific example illustrated in FIG. 13 as in the specific example of the second embodiment illustrated in FIG. 5, the balun transformer 50 includes a common mode choke 40 and a Ruthroff type transmission line transformer 41, which are arranged in a cascading connection. The second end TB2 of a secondary line 40B of the common mode choke 40 and the third end TB3 of a secondary line 41B of the Ruthroff type transmission line transformer 41 are connected to each other and are connected to the power supply terminal 30 with the choke coil Lck2 interposed therebetween.

The power supply voltage Vcc is applied to the output node Nout2 on one side of the Class E amplifier 20 via the choke coil Lck2, the secondary line 41B of the Ruthroff type transmission line transformer 41, and a primary line 40A of the common mode choke 40. In addition, the power supply voltage Vcc is applied to the output node Nout1 on the other side of the Class E amplifier 20 via the choke coil Lck2 and the secondary line 40B of the common mode choke 40. For direct current, the DC-cut capacitor Cdc2 separates the power supply voltage Vcc from ground potential.

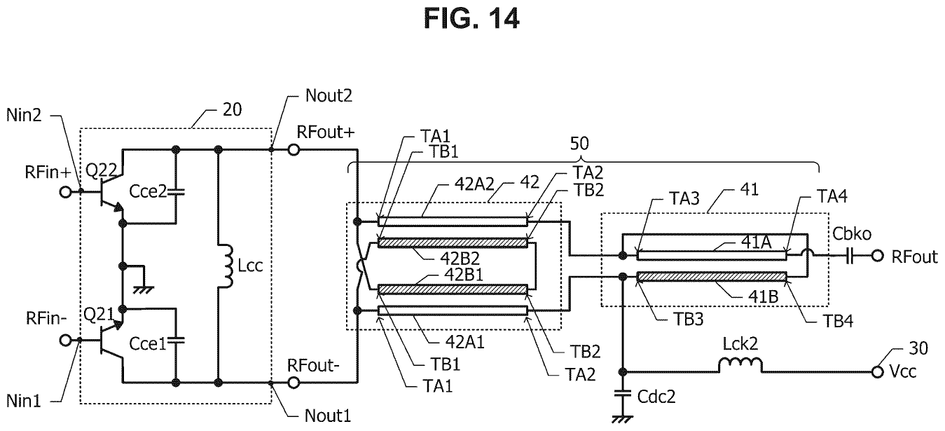

FIG. 14 is an equivalent circuit diagram illustrating another specific example of the differential power amplifier according to the third embodiment. In the specific example illustrated in FIG. 14 as in the specific example of the second embodiment illustrated in FIG. 8, the balun transformer 50 includes a Guanella type transmission line transformer 42 and a Ruthroff type transmission line transformer 41, which are arranged in a cascading connection. The second end TA2 of a primary line 42A1 of the Guanella type transmission line transformer 42 and the third end TB3 of a secondary line 41B of the Ruthroff type transmission line transformer 41 are connected to each other and are connected to the power supply terminal 30 with the choke coil Lck2 interposed therebetween.

The power supply voltage Vcc is applied to the output node Nout1 on one side of the Class E amplifier 20 via the choke coil Lck2 and the primary line 42A1 of the Guanella type transmission line transformer 42. In addition, the power supply voltage Vcc is applied to the output node Nout2 on the other side of the Class E amplifier 20 via the choke coil Lck2, the secondary line 41B of the Ruthroff type transmission line transformer 41, and a primary line 42A2 of the Guanella type transmission line transformer 42. For direct current, the DC-cut capacitor Cdc2 separates the power supply voltage Vcc from ground potential.

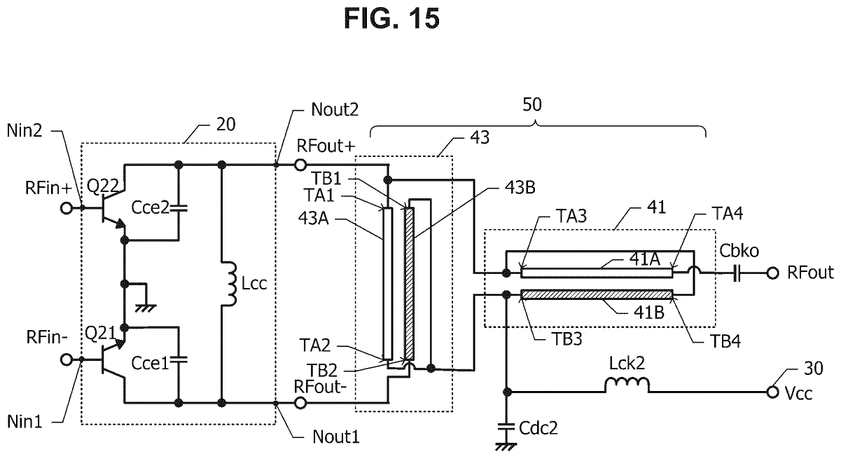

FIG. 15 is an equivalent circuit diagram illustrating a still another specific example of the differential power amplifier according to the third embodiment. In the specific example illustrated in FIG. 15 as in the specific example of the second embodiment illustrated in FIG. 11, the balun transformer 50 includes a first Ruthroff type transmission line transformer 43 and a second Ruthroff type transmission line transformer 41, which are arranged in a cascading connection. The second end TA2 of a primary line 43A of the first Ruthroff type transmission line transformer 43 and the third end TB3 of a secondary line 41B of the second Ruthroff type transmission line transformer 41 are connected to each other and are connected to the power supply terminal 30 with the choke coil Lck2 interposed therebetween.

The power supply voltage Vcc is applied to the output node Nout2 on one side of the Class E amplifier 20 via the choke coil Lck2 and the primary line 43A of the first Ruthroff type transmission line transformer 43. In addition, the power supply voltage Vcc is applied to the output node Nout1 on the other side of the Class E amplifier 20 via the choke coil Lck2 and a secondary line 43B of the first Ruthroff type transmission line transformer 43. For direct current, the DC-cut capacitor Cdc2 separates the power supply voltage Vcc from ground potential.

In the specific examples of the third embodiment illustrated in FIGS. 13, 14, and 15, multiple transmission lines of the balun transformer 50 are directly connected to each other without necessarily a DC-cut capacitor interposed therebetween. Thus, two transmission lines may be formed as a single continuous conductor trace.

### Fourth Embodiment

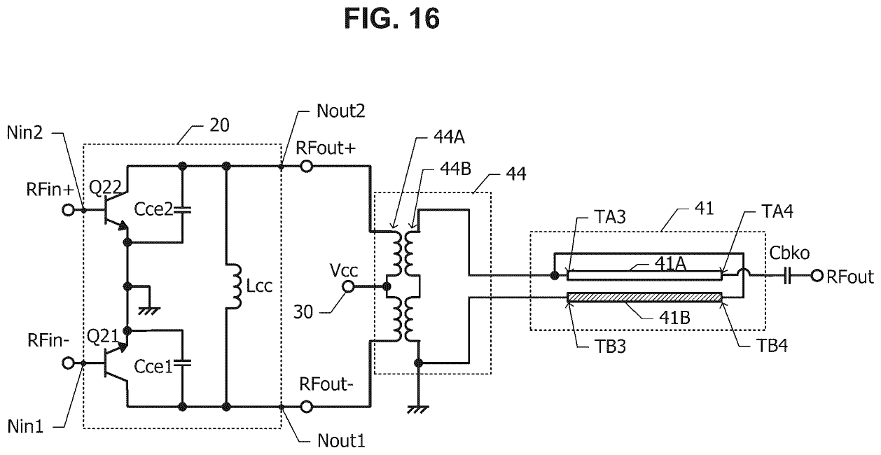

Next, referring to FIG. 16, description will be given with regard to a differential power amplifier according to a fourth embodiment. Description will be omitted herein with regard to the configuration that is the same as the configuration of the differential power amplifier according to the second embodiment (FIG. 2).

FIG. 16 is an equivalent circuit diagram of the differential power amplifier according to the fourth embodiment. Instead of the choke coils Lck21 and Lck22 and the balun transformer 50 in the second embodiment (FIG. 2), a magnetically coupled transformer 44 and a Ruthroff type transmission line transformer 41 are included in the fourth embodiment. The configuration of the Ruthroff type transmission line transformer 41 is the same as the configuration of the Ruthroff type transmission line transformer 41 in the specific example of the second embodiment illustrated in FIG. 3.

The magnetically coupled transformer 44 includes a primary coil 44A and a secondary coil 44B magnetically coupled to each other. Both ends of the primary coil 44A are connected one each to the two output nodes Nout1 and Nout2 of the Class E amplifier 20. One end of the secondary coil 44B is connected to ground potential, and the other end is connected to the third end TA3 of a primary line 41A of the Ruthroff type transmission line transformer 41.

The center tap of the primary coil 44A of the magnetically coupled transformer 44 is connected to the power supply terminal 30. The power supply voltage Vcc is supplied to the two output nodes Nout1 and Nout2 of the Class E amplifier 20 via the primary coil 44A. The primary coil 44A of the magnetically coupled transformer 44 is also configured to serve as a choke inductor.

The turns ratio of the magnetically coupled transformer 44 is 1:1. The magnetically coupled transformer 44 is configured to serve as a balun. The Ruthroff type transmission line transformer 41 is configured to serve as an impedance converting circuit and a band elimination filter.

Next, description will be given with regard to a positive effect of the differential power amplifier according to the fourth embodiment.

Since the first inductor Lcc is disposed separately from the primary coil 44A of the magnetically coupled transformer 44 configured to serve as the choke coil for power supply also in the fourth embodiment as in the first embodiment, leakage of a noise signal from the power supply terminal 30 and parasitic oscillation may be reduced or prevented.

Since the turns ratio of the magnetically coupled transformer is 1:1, an increase in the inter-line capacitance of the windings may be reduced or prevented. Consequently, the magnetically coupled transformer 44 is unlikely to hamper radio-frequency operation or broad-band operation. The magnetically coupled transformer 44 configured to serve as a balun has a function of attenuating even harmonics, and the Ruthroff type transmission line transformer 41 has a function of attenuating the third harmonic. Thus, a band pass filter configured to pass only the fundamental may be provided by using the magnetically coupled transformer 44 and the Ruthroff type transmission line transformer 41.

The above embodiments are described for illustration, and partial substitutions or combinations of the configurations described in different embodiments are obviously feasible. Similar operations and similar effects achievable by similar configurations described in multiple embodiments are not individually described in each of the embodiments. Further, the present disclosure is not limited to the above embodiments. For example, it should be apparent to those skilled in the art that various kinds of modification, improvement, combination, and the like are feasible.

### REFERENCE SIGNS LIST

20 Class E amplifier
30 power supply terminal
40 common mode choke
40A primary line of common mode choke
40B secondary line of common mode choke
41 Ruthroff type transmission line transformer
41A primary line of Ruthroff type transmission line transformer
41B secondary line of Ruthroff type transmission line transformer
42 Guanella type transmission line transformer
42A1, 42A2 primary line of Guanella type transmission line transformer
42B1, 42B2 secondary line of Guanella type transmission line transformer
43 first Ruthroff type transmission line transformer
43A primary line of first Ruthroff type transmission line transformer
43B secondary line of first Ruthroff type transmission line transformer
44 magnetically coupled transformer
44A primary coil
44B secondary coil
50 balun transformer
60 driver-stage amplifier
61 first bias circuit
62 matching network
63 balun matching network
64 second bias circuit

1. A differential power amplifier comprising:
a Class E amplifier having two input nodes and two output nodes, and configured to amplify a differential signal;
a power supply terminal configured to receive a power supply voltage; and
at least one choke inductor connecting the two output nodes to the power supply terminal,
wherein the Class E amplifier comprises:
two transistors each having a base or a gate connected to a corresponding one of the two input nodes, and a collector or a drain connected to a corresponding one of the two output nodes,
two first capacitors each connected between the collector or the drain and an emitter or a source of a corresponding one of the two transistors, and
a first inductor connected between the collector or the drain of one of the two transistors, and the collector or the drain of the other of the two transistors.

2. The differential power amplifier according to claim 1,
wherein the at least one choke inductor comprises a first inductor connecting one of the two output nodes to the power supply terminal and a second inductor connecting the other of the two output nodes to the power supply terminal.

3. The differential power amplifier according to claim 2, further comprising:
a common mode choke comprising a primary line and a secondary line,
wherein a first end of the primary line of the common mode choke and a first end of the secondary line of the common mode choke are each connected to different ones of the two output nodes, and a second end of the secondary line of the common mode choke is connected to a ground potential at least for alternating current.

4. The differential power amplifier according to claim 3, further comprising:
a Ruthroff type transmission line transformer comprising a primary line and a secondary line,
wherein a first end of the primary line of the Ruthroff type transmission line transformer is connected to a second end of the secondary line of the Ruthroff type transmission line transformer,
wherein the first end of the primary line of the Ruthroff type transmission line transformer is connected to a second end of the primary line of the common mode choke, and a first end of the secondary line of the Ruthroff type transmission line transformer is connected to the ground potential at least for alternating current.

5. The differential power amplifier according to claim 3, further comprising:
at least one DC-cut capacitor configured to separate each of the two output nodes from the ground potential for direct current.

6. The differential power amplifier according to claim 4, further comprising:
at least one DC-cut capacitor configured to separate each of the two output nodes from the ground potential for direct current.

7. The differential power amplifier according to claim 2, further comprising:
a Guanella type transmission line transformer comprising two transmission lines, each comprising a primary line and a secondary line,
wherein first ends of the two primary lines of the Guanella type transmission line transformer are each connected to different ones of the two output nodes, and
wherein a second end of one of the two primary lines of the Guanella type transmission line transformer is connected to a ground potential at least for alternating current.

8. The differential power amplifier according to claim 7, further comprising:
a Ruthroff type transmission line transformer comprising a primary line and a secondary line,
wherein a first end of the primary line of the Ruthroff type transmission line transformer is connected to second ends of the two primary lines of the Guanella type transmission line transformer, and
wherein a second end of the secondary line of the Ruthroff type transmission line transformer is connected to the ground potential at least for alternating current.

9. The differential power amplifier according to claim 7, further comprising:
at least one DC-cut capacitor configured to separate each of the two output nodes from the ground potential.

10. The differential power amplifier according to claim 8, further comprising:
at least one DC-cut capacitor configured to separate each of the two output nodes from the ground potential.

11. The differential power amplifier according to claim 2, further comprising:
a first Ruthroff type transmission line transformer comprising a primary line and a secondary line,
wherein a first end of the primary line of the first Ruthroff type transmission line transformer is connected to one of the two output nodes,
wherein a second end of the primary line of the first Ruthroff type transmission line transformer is connected to a first end of the secondary line of the first Ruthroff type transmission line transformer,
wherein a second end of the secondary line of the first Ruthroff type transmission line transformer is connected to the other of the two output nodes, and
wherein the second end of the primary line of the first Ruthroff type transmission line transformer and the first end of the secondary line of the first Ruthroff type transmission line transformer are connected to a ground potential at least for alternating current.

12. The differential power amplifier according to claim 11, further comprising:
a second Ruthroff type transmission line transformer comprising a primary line and a secondary line,
wherein a first end of the primary line of the second Ruthroff type transmission line transformer is connected to the first end of the primary line of the first Ruthroff type transmission line transformer, and
wherein a first end of the secondary line of the second Ruthroff type transmission line transformer is connected to the ground potential at least for alternating current.

13. The differential power amplifier according to claim 11, further comprising:
at least one DC-cut capacitor configured to separate each of the two output nodes from the ground potential for direct current.

14. The differential power amplifier according to claim 12, further comprising:
at least one DC-cut capacitor configured to separate each of the two output nodes from the ground potential for direct current.

15. The differential power amplifier according to claim 1, further comprising:
a transmission line transformer configured to convert a differential signal that is output from the two output nodes into a single-ended signal, and to perform impedance conversion,
wherein the at least one choke inductor is connected to each of the two output nodes with the transmission line transformer interposed therebetween.

16. The differential power amplifier according to claim 1, further comprising:
a magnetically coupled transformer comprising a primary coil and a secondary coil magnetically coupled to each other,
wherein each end of the primary coil is connected one of the two output nodes,
wherein a first end of the secondary coil is connected to a ground potential,
wherein a center tap of the primary coil is connected to the power supply terminal, and
wherein the at least one choke inductor comprises the primary coil of the magnetically coupled transformer.
